(19) United States
(12) Patent Application Publication
(10) Pub. No.: US 2003/0036262 A1
(43) Pub. Date: Feb. 20, 2003

(54) Method for manufacturing multilayer ceramics with improved interlayer bonding

(75) Inventors: Dong-Soo Park, Kyungsangnam-do (KR); Hai-Doo Kim, Kyungsangnam-do (KR); Byung-Dong Hahn, Kyungsangnam-do (KR)

Correspondence Address: Richard S. Milner, Cooper & Dunham LLP, 1185 Avenue of the Americas, New York, NY, 10036, US

(73) Assignee: Korea Institute Of Machinery & Materials, Changwon-shi (KR)

(21) Appl. No.: 10/038,183

(22) Filed: Jan. 2, 2002

(30) Foreign Application Priority Data
Aug. 17, 2001 (KR) 2001-49672

(51) Int. Cl. H01L 21/4763; H01L 29/12

(52) U.S. Cl. 438/624; 252/62.3 R

(57) ABSTRACT

Disclosed is a method for manufacturing multilayer ceramics, and in particular, a method for manufacturing multilayer ceramics with improved interlayer bonding by laminating ceramic tapes manufactured from slurry under vacuum and sintering them. The method comprises the steps of: admixing an organic substance comprising a dispersion agent, a plasticizer, and a binder with ceramic powder to give slurry; defoaming the ceramic slurry under vacuum, followed by casting the defoamed ceramic slurry into ceramic tapes; laminating the ceramic tapes at room temperature to 100° C. under vacuum less than 1 atm; burning out the organic substances from the ceramic tapes laminated under vacuum; and sintering the laminated ceramic tapes free of organic substances. The method prevent air or other gases from being trapped in a space between ceramic layers to increase a interlayer binding force by laminating ceramic tapes at room temperature or higher under vacuum, thereby a yield and reliability of multilayer ceramic products are improved.

### BACKGROUND OF THE INVENTION

1. Field of the Invention

The present invention relates, in general, to a method for manufacturing multilayer ceramics with improved interlayer bonding, and in particular, to a method for manufacturing multilayer ceramics with improved interlayer bonding by laminating ceramic tapes manufactured from slurry under vacuum and sintering them.

2. Description of the Prior Art

Generally, multilayer ceramics are used to manufacture parts such as a multilayer ceramic condenser, a multilayer ceramic actuator, a chip filter, and a microwave filter, and it is expected that demand for multilayer ceramics and multilayer ceramic parts having various shapes and dimensions will be increased. Conventionally, a multilayer ceramic laminated body is manufactured by uniformly mixing ceramics and organic substances, forming the resulting mixture in the shape of thin tape through a tape casting process and drying it, printing circuits on the resulting structure and cutting the resulting ceramic tapes in desired shapes, and laminating cut ceramic tapes and heating the laminated ceramic tapes.

However, air or other gas is trapped between layers of ceramic tapes during the lamination, so that a bonding between layers is poor, and a yield and a reliability of a product are lowered. Particularly, the larger the dimensions of the product are, the poorer the yield and the reliability of the product is.

To avoid the above disadvantages, secondary pressing can be conducted for increasing an interlayer bonding, but gas in a space between layers cannot be completely removed, and gas in the space forms large pores after performing a binder burn-out step. Therefore, performance of products is lowered even though laminated ceramic tapes are further sintered.

### SUMMARY OF THE INVENTION

Therefore, it is an object of the present invention to avoid disadvantages of prior arts, and to provide a method for manufacturing multilayer ceramics with improved interlayer bonding, in which slurry is manufactured by mixing organic substances containing a dispersion agent, a plasticizer, and a binder with ceramic powder, and then ceramic tapes manufactured from slurry are laminated under vacuum, and thereafter organic substances of ceramic tapes laminated under vacuum are burned out, followed by sintering the laminated ceramic tapes.

Based on the present invention, the above object can be accomplished by a provision of a method for manufacturing multilayer ceramics with improved interlayer bonding, comprising the steps of: admixing an organic substance comprising a dispersion agent, a plasticizer, and a binder with ceramic powder to give slurry; defoaming the ceramic slurry under vacuum, followed by casting the defoamed ceramic slurry into ceramic tapes; laminating the ceramic tapes at room temperature to 100° C. under vacuum; burning out the organic substances from the ceramic tapes laminated under vacuum; and sintering the laminated ceramic tapes free of organic substances.

Furthermore, the above object can be accomplished by provision of the method for manufacturing multilayer ceramics with improved interlayer bonding, wherein the laminating step is carried out under a vacuum lower than 1 atm with pressing of the ceramic tapes and the vacuum is set by sealing a space around cut ceramic tapes and exhausting air in the space.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a flow chart schematically illustrating a manufacture of multilayer ceramics with improved interlayer bonding according to the present invention;

FIG. 2A is a photograph illustrating a device for laminating ceramic tapes under vacuum according to the present invention;

FIG. 2B is a front elevation view illustrating a device for laminating ceramic tapes under vacuum according to the present invention;

FIG. 3 illustrates photographs of a surface and a cross section of ceramics laminated under vacuum according to the present invention;

FIG. 4 illustrates a photograph of a surface of ceramics whose organic substances are burned out, laminated under vacuum according to the present invention;

FIG. 5 illustrates photographs of a surface and a cross section of ceramic tapes laminated under atmospheric pressure; and

FIG. 6 illustrates a photograph of a broken ceramic laminated body, after organic substances of ceramic tapes laminated under atmospheric pressure are burned out.

### DETAILED DESCRIPTION OF THE INVENTION

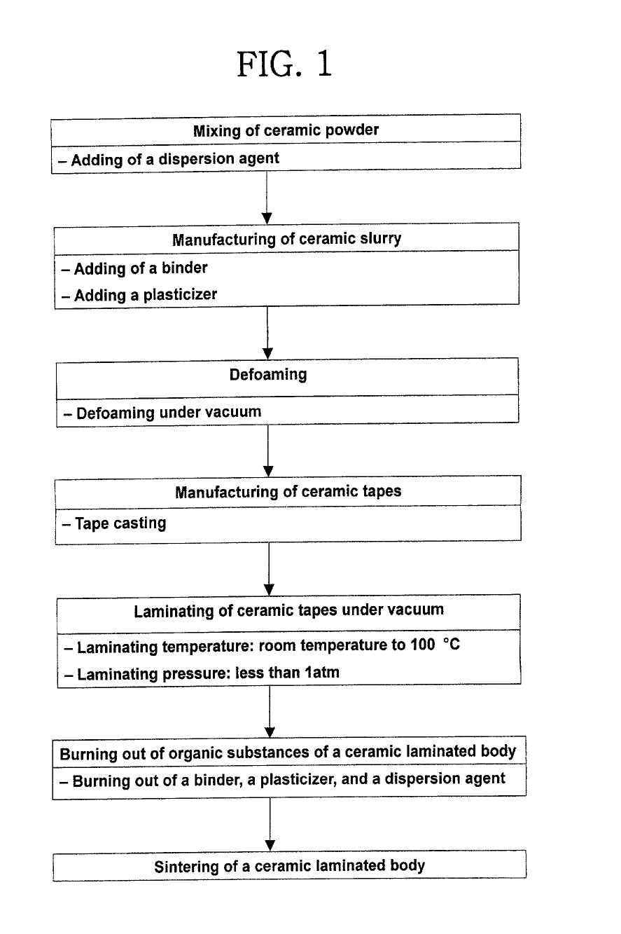

FIG. 1 is a flow chart schematically illustrating a manufacture of multilayer ceramics with improved interlayer bonding according to the present invention. With reference to FIG. 1, in order to manufacture multilayer ceramics with improved interlayer bonding, a certain amount of ceramic powders having a desired composition is mixed with a properly selected dispersion agent, the amount of which is controlled according to the amount of ceramic powder.

Generally, ceramic powder is mechanically mixed with the dispersion agent through a Ball Mill mixing process for a predetermined time. A binder and a plasticizer are mixed with the resulting ceramic powder during the predetermined time to manufacture slurry for tape casting.

Then, slurry is defoamed under vacuum, and is subjected to a tape casting process to manufacture ceramic tapes having a desired thickness.

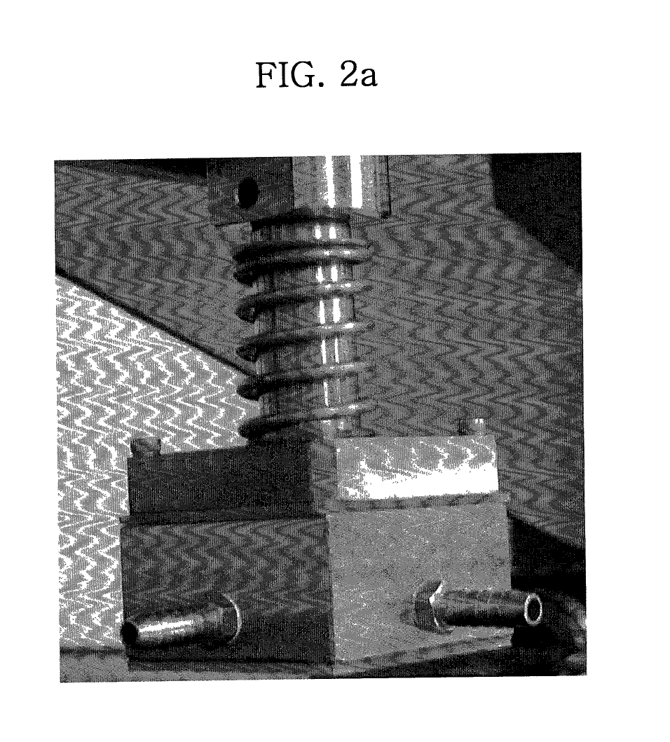

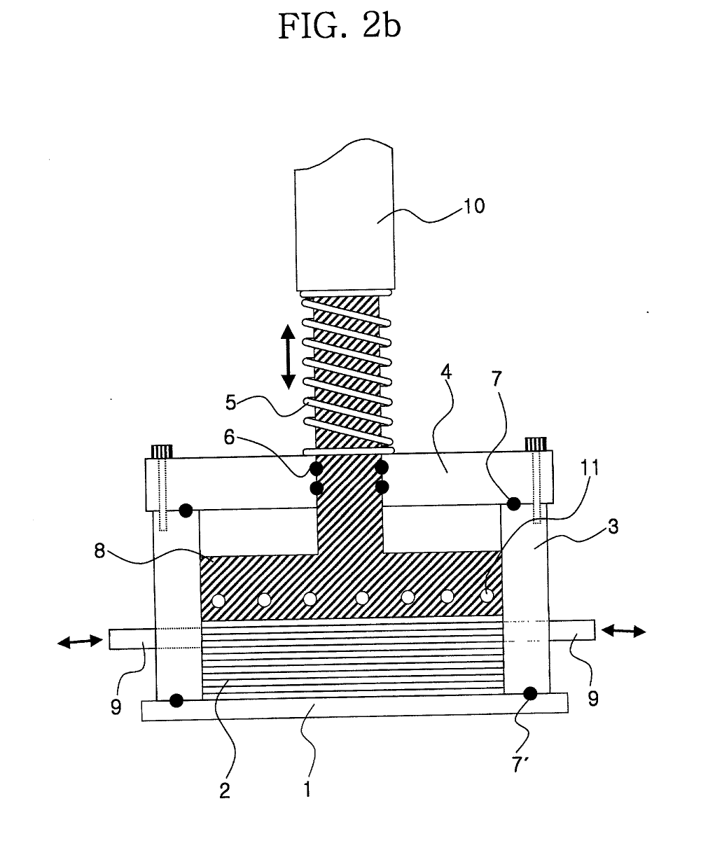

Referring to FIGS. 2a and 2b, ceramic tapes are laminated in a laminating mold 3 of a device for laminating ceramic tapes under vacuum according to the present invention, then a pressing punch 8 connected to a press 10 is contacted to an upper side of a laminated body of ceramic tapes 2. Three way valves (not shown in FIGS. 2a and 2b) are connected to suction/exhaust pipe 9, and any one of two ports of the three way valve, which are not connected to the suction/exhaust pipe, is connected to a vacuum pump (not shown in FIGS. 2a and 2b). Air in the laminating mold 3 is exhausted to an outside of the mold through the three way valve connected to the vacuum pump, and thus an inside of the mold can be maintained under vacuum less than 1 atm. Thereafter, ceramic tapes 2 are pressed by the pressing punch 8 and laminated. One remaining port of the three way valve is exposed to atmosphere.

In the device used for laminating ceramic tapes under vacuum according to the present invention, rubber rings 6 for sealing are inserted between the pressing punch 8 connected with the press 10 and the laminating mold 3, and also rubber rings 7 and 7′ for sealing are respectively inserted between a mold cap 4 and the laminating mold 3, and a base plate 1 and the laminating mold 3 in order to maintain an inside of the laminating mold under vacuum, as shown in FIGS. 2A and 2B.

According to the present invention, a heater 11 may be provided in a lower portion of the pressing punch 8 connected with ceramic tapes so that ceramic tapes are laminated at a room temperature to 100° C.

To increase adhesiveness of organic components comprising a binder in ceramic tapes, ceramic tapes are laminated at a room temperature to 100° C. For example, when the temperature is higher than 100° C., a strength of ceramic tapes is reduced, and so ceramic tapes are easily deformed by pressing.

After ceramic tapes are laminated under vacuum, the three way valve is switched from the passage of vacuum pump-suction/exhaust pipe to the passage of atmosphere-suction/exhaust pipe, thereby atmospheric air is allowed to flow through the suction/exhaust pipe 9 into an interior of the laminating mold. Then, laminated ceramic tapes 2 are pulled out under atmospheric pressure.

As described above, a laminated body of ceramic tapes laminated under vacuum has a dense inner structure and an increased interlayer binding force.

Meanwhile, laminated ceramic tapes contain organic substances added in each step, such as the binder. Organic substances are burned out by maintaining organic substances for a long time while atmospheric temperature is slowly raised. Finally, ceramic tapes are sintered at proper sintering temperature under sintering atmosphere.

A better understanding of the present invention may be obtained in light of the following examples which are set forth to illustrate, but are not to be construed to limit the present invention.

### EXAMPLE

92 g of silicon nitride powder (Si₃N₄), 6 g of yttrium oxide powder (Y₂O₃), 2 g of aluminum oxide powder (Al₂O₃), 3 g of a dispersion agent, i.e. Hypermer KDI (ICI Chemical Co., London, UK), 1671 ml of methyl ethyl ketone as a solvent, and a silicon nitride ball with a diameter of 5 mm were discharged into a MC Nylon Jar, and admixed for 4 hours with the use of Planetary Ball Mill. In order to maximally prevent contamination by impurities, the silicon nitride ball and MC Nylon Jar were used.

After that, 27 g of poly vinyl-butyral, i.e. a binder, and 27 g of di-butyl phthalate, i.e. a plasticizer, were added into the MC Nylon Jar, and then admixed for 4 hours to produce slurry for tape casting.

Slurry was defoamed under vacuum, and a ceramic tape with a thickness of 0.25 mm was manufactured on a mylar film coated with silicone by use of a tape caster. The ceramic tapes were cut to form regular quadrilateral sheets having a side length of 34 mm, and disposed on a stainless steel plate at regular intervals, followed by insertion into a laminating mold of a device for laminating ceramic tapes under vacuum according to the present invention. Thereafter, the pressing punch was contacted to an upper side of a ceramic laminated body. Next, air in the laminating mold was exhausted to an outside of the mold through the suction/exhaust pipe of one side of the laminating mold, which was connected to the vacuum pump, thereby an inside space of the mold was maintained under vacuum less than 1 atm.

After that, laminated ceramic tapes were pressed by lowering the pressing punch and laminated. Then, the suction/exhaust pipe of one side of the laminating mold was exposed to atmosphere so that air was allowed to flow to an inside space of the laminating mold, thereby the inside pressure of the mold became atmospheric pressure. Next, the pressing punch and the laminating mold lowered for forming an airtight space were raised in order to laminate other ceramic tapes. This procedure was repeated for other ceramic sheets, thereby ceramic sheets were laminated under vacuum.

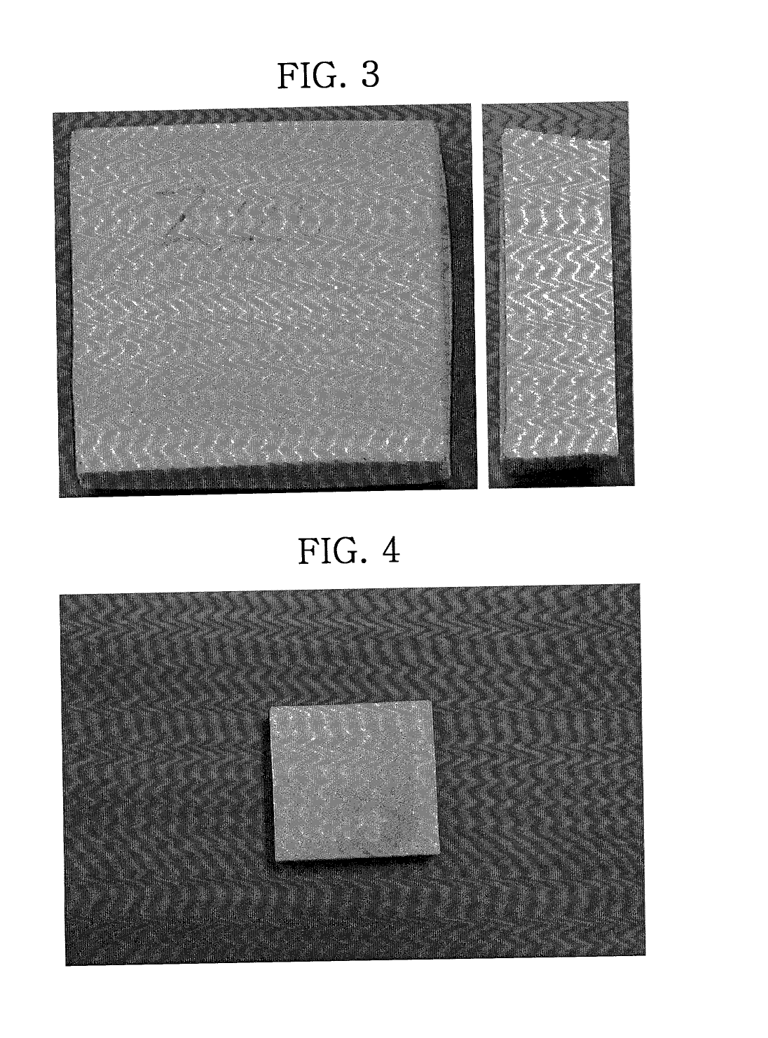

FIG. 3 illustrates photographs of a surface and a cross section of ceramics laminated under vacuum according to the present invention, and FIG. 4 illustrates a photograph of a surface of ceramics whose organic substances are burned out, laminated under vacuum according to the present invention.

With reference to FIG. 3, ceramic tapes laminated under vacuum have a dense inner structure. Laminated ceramic tapes were heated at a rate of 2.5° C./min to 420° C., and left at 420° C. for 10 hours, thereby organic substances of ceramic tapes were burned out. Through the above procedures, multilayer ceramics having a dense inner structure and a smooth surface were manufactured, as shown in FIG. 4.

The multilayer ceramics were sintered for 4 hours in a nitrogen-pressurized sintering furnace with the use of nitrogen at 1875° C. under 20 atm to manufacture multilayer ceramics with 94% homogenous solid compaction.

### COMPARATIVE EXAMPLE

The procedures of the example were repeated except that ceramic tapes were laminated under atmospheric pressure.

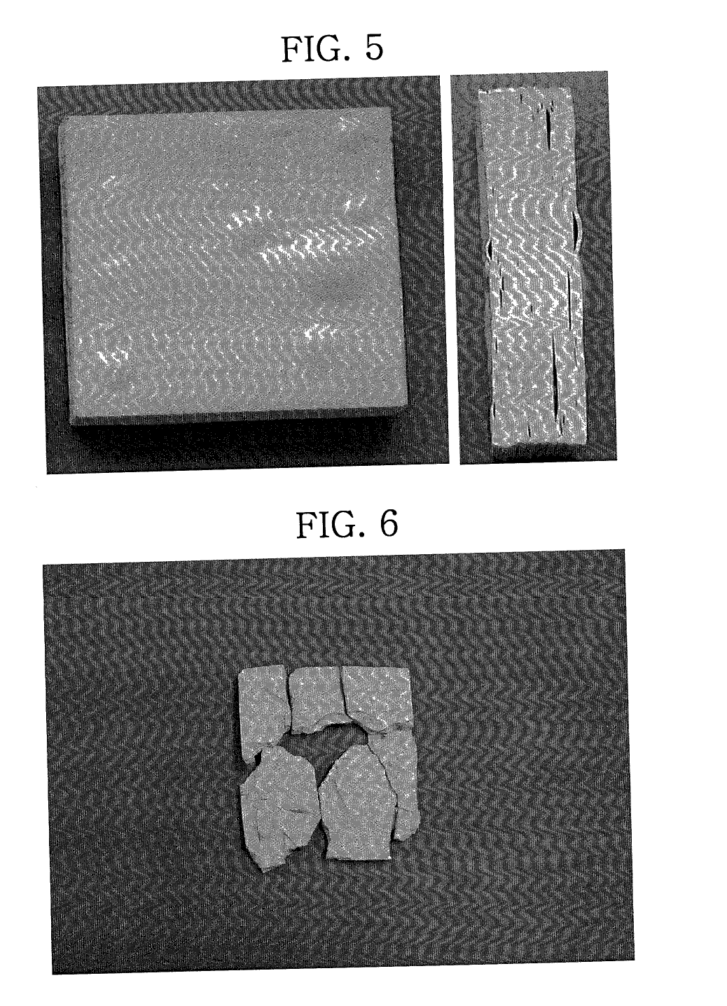

FIG. 5 illustrates photographs of a surface and a cross section of ceramic tapes laminated under atmospheric pressure.

Referring to FIG. 5, a laminated body of ceramic tapes has an uneven surface because layers are not closely contacted to each other owing to air bubbles existing between layers.

Now turning to FIG. 6, after organic substances of ceramic tapes laminated under atmospheric pressure are burned out, the laminated body of ceramic tapes is broken owing to air bubbles existing between layers of ceramic tapes.

As described above, the present invention prevents air or other gas from being trapped in a space between ceramic layers to increase an interlayer binding force while laminating ceramic tapes at room temperature or higher under vacuum, thereby a yield and reliability of multilayer ceramic products are improved.

The present invention has been described in an illustrative manner, and it is to be understood that the terminology used is intended to be in the nature of description rather than of limitation. Many modifications and variations of the present invention are possible in light of the above teachings. Therefore, it is to be understood that within the scope of the appended claims, the invention may be practiced otherwise than as specifically described.

What is claimed is:

1. A method for manufacturing multilayer ceramics, comprising the steps of:
admixing an organic substance with ceramic powder to give slurry, said organic substance comprising a dispersion agent, a plasticizer, and a binder;
defoaming the ceramic slurry under vacuum, followed by casting the defoamed ceramic slurry into ceramic tapes;
laminating the ceramic tapes at room temperature to 100° C. under vacuum;
burning out the organic substances from the ceramic tapes laminated under vacuum; and
sintering the laminated ceramic tapes free of organic substances
whereby the multilayer ceramics can be improved in interlayer binding force.

2. The method according to claim 1, wherein the laminating step is carried out under a vacuum lower than 1 atm with pressing of the ceramic tapes, said vacuum being set by sealing a space around cut ceramic tapes and exhausting air in the space.
